(19) United States
(12) Patent Application Publication
(10) Pub. No.: US 2021/0305481 A1
(43) Pub. Date: Sep. 30, 2021

(54) PIEZOELECTRIC RESONANT SHUNT DAMPING FOR PHASE NOISE REDUCTION

(71) Applicant: BAE Systems Information and Electronic Systems Integration Inc., Nashua, NH (US)

(72) Inventors: Maxwell L. Affleck, New Boston, NH (US); Shawn P. Sharp, Nashua, NH (US); Mike Pena, Goffstown, NH (US); Allison Moulton, New Hartford, NY (US)

(21) Appl. No.: 17/265,385

(22) PCT Filed: Oct. 4, 2018
(86) PCT No.: PCT/US18/54288

§ 371 Date: Feb. 2, 2021

(51) Int. Cl. H01L 41/04; F16F 15/00; H01L 41/09

(52) U.S. Cl. CPC H01L 41/042; F16F 15/007; F16F 15/002; F16F 2230/18; F16F 2224/0283; F16F 2228/066; H01L 41/0973

(57) ABSTRACT

The system and method for phase noise reduction and/or vibration reduction in assemblies using piezoelectric passive resonant shunt damping or active vibration cancellation/compensation techniques. In some cases a circuit card or similar structure comprises an embedded piezoelectric device to reduce the effects of vibration on any sensitive device or component thereon. The system has a resonant shunt circuit or other control circuit to provide electrical loading to the piezoelectric device and may be single frequency mode or multimodal. The system may also be adaptively controlled by a microprocessor or the like, so that the vibration sensitive devices are monitored and controlled over time to extend the life of the device.

### FIELD OF THE DISCLOSURE

The present disclosure relates to phase noise or vibration reduction for oscillators, clocks, or other vibration sensitive components, and more particularly to the use of a piezoelectric bending actuator to convert mechanical bending energy to electrical energy when exposed to vibrations.

### BACKGROUND OF THE DISCLOSURE

Traditional techniques for vibration reduction do not typically occur at the circuit card level. Often vibration mitigation at the circuit card level comes with significant packaging or form factor design changes. The technique of the present disclosure adds minimal thickness to a circuit card design, and only a few small surface mounted components. Existing solutions also tend to shift the resonant frequency, where the technique of the present disclosure simply reduces the resulting response with no natural frequency shift. Typically, compensation for phase noise is accounted for in software and firmware, rather than mechanical mitigation techniques as described herein.

It is understood that there is inherent performance derogation due to vibration. Firmware and/or software techniques do not necessarily account for vibration effects; instead these techniques focus on signal processing techniques to attempt to get the “best” performance possible out of the device without accounting for vibration effects.

Wherefore it is an object of the present disclosure to overcome the above-mentioned shortcomings and drawbacks associated with the conventional vibration reduction and phase noise reduction techniques. The end-game of the vibration reduction is to limit the structural vibration amplification to which vibration sensitive components, such as oscillators or clocks are exposed.

### SUMMARY OF THE DISCLOSURE

One aspect of the present disclosure is a method of reducing the motion of a vibration sensitive component, comprising: providing a structure comprising at least one vibration sensitive component; analyzing the structure to determine at least one critical mode shape and/or natural frequency of the structure to be attenuated; placing a piezoelectric device in a high strain location of the structure, the piezoelectric device being configured to be used for vibration attenuation at the at least one critical mode shape and/or natural frequency of the structure; providing the piezoelectric device with electrical input; and controlling the piezoelectric device with a control circuit to attenuate vibration at the at least one critical mode shape and/or natural frequency of the structure.

One embodiment of the method of reducing the motion of a vibration sensitive component is wherein the piezoelectric device is embedded in the structure. In certain embodiments, the vibration sensitive component is an oscillator and/or a clock. In some cases, phase noise is reduced.

Another embodiment of the method of reducing the motion of a vibration sensitive component is wherein the vibration sensitive component is an optical device. In some cases, the structure is a circuit card assembly.

Yet another embodiment of the method of reducing the motion of a vibration sensitive component is wherein the control circuit includes, but is not limited to, a resonant shunt circuit of an inductor and resistor tuned to at least one critical frequency, or an active control mechanism including an electrical design that provides a negative waveform of that of the environment.

In still yet another embodiment, the method of reducing the motion of a vibration sensitive component further comprises tuning an electrical shunt circuit and electrically connecting it to the piezoelectric device, thereby shunting structural excitations that occur in the structure and/or the connected vibration sensitive components. In some cases, the method of reducing the motion of a vibration sensitive component further comprises providing adaptive control of the control circuit. In certain embodiments, the method further comprises feedback control to accurize the active control of the control circuit.

In certain embodiments, the method of reducing the motion of a vibration sensitive component further comprises a microcontroller to address changing resistor and inductor values to allow for adaptation to vibrations within the environment. In some cases, the method further comprises designing the structure around one or more vibration sensitive components.

Another aspect of the present disclosure is a system for reducing the motion of a vibration sensitive component, comprising: a structure comprising at least one vibration sensitive component, the structure having at least one critical mode shape and/or natural frequency; a piezoelectric device located in a high strain location of the structure, the piezoelectric device being configured to be used for vibration attenuation of the at least one critical mode shape and/or natural frequency of the structure; and a control circuit in electrical connection with the piezoelectric device for controlling vibration attenuation at the at least one critical mode shape and/or natural frequency of the structure.

One embodiment of the system for reducing the motion of a vibration sensitive component is wherein the control circuit includes but is not limited to a resonant shunt circuit of an inductor and resistor tuned to at least one critical frequency, or an active control mechanism including an electrical design that provides a negative waveform of that of the environment.

Another embodiment of the system further comprises tuning an electrical shunt circuit electrically connected to the piezoelectric device, thereby shunting structural excitations that occur in the structure and/or the connected vibration sensitive components. In some cases, the system for reducing the motion of a vibration sensitive component further comprises a synthetic inductor.

Yet another embodiment of the system for reducing the motion of a vibration sensitive component further comprises adaptive control of the control circuit. In some cases, the structure is a circuit card assembly and the piezoelectric device is embedded in the structure. In certain embodiments, the system further comprises one or more of a processor, a proportional-integral-derivative (PID) controller, an adaptive controller for the control circuit, an a lead lag compensator.

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1 shows one embodiment of the system of the present disclosure.

FIG. 2 shows the first mode resonant frequency and mode shape of one embodiment of the present disclosure.

FIG. 3 shows a vibration frequency plot of a first embodiment of the present disclosure both shunted and un-shunted.

FIG. 4 shows a vibration frequency plot of a second embodiment of the present disclosure both shunted and un-shunted.

FIG. 5 shows one embodiment of the system of the present disclosure.

FIG. 6 shows one embodiment of a method according to the principles of the present disclosure.

### DETAILED DESCRIPTION OF THE DISCLOSURE

One embodiment of the present disclosure is a system and method for addressing the improved phase noise performance of an oscillator, reduction of solder joint fatigue, and increasing circuit card survivability issues due to mechanical vibration and shock inputs to the circuit card in which said devices are mounted.

In one embodiment, a piezoelectric bending actuator is embedded within a cavity of a 3D printed circuit card assembly (CCA). In some cases, the piezoelectric bending actuator is embedded in a traditionally manufactured CCA, or some other structure to which vibration sensitive components are mounted. In other embodiments, the piezoelectric bending actuator is mounted to the surface of a structure, including, but not limited to a CCA, using epoxy or the like. When the CCA or other structure is exposed to vibration in its environment, the mechanical bending energy is converted to electrical energy via the piezoelectric device. Incorporated on the CCA or other structure is the control circuitry for the piezoelectric element.

In certain embodiments, the CCA or other structure has one or more resistors with one or more inductors in any combination of parallel or series for passive resonant shunt damping or an equivalent operational amplifier circuit. In certain embodiments, the CCA or other structure has a synthetic inductor, or low pass filter, with a tuned natural frequency equivalent to the fundamental frequency of the mechanical assembly as well as one or more resistors for use in passive resonant shunt damping.

In another embodiment, the system of the present disclosure is used for active vibration cancellation/compensation. In certain embodiments, the piezoelectric element is used as both an actuator and a sensor. In some cases, the system utilizes a linear control algorithm where system parameters are known, such as Lead-Lag, PID control, or opposite wave generation in order to actively control the actuation of the piezoelectric element. In other embodiments, the system utilizes a nonlinear control algorithm, using a microprocessor and power source, for adaptive control. In some cases, system structural health can be monitored for significant resonant shifts over time due to impending structural failure.

In yet another embodiment, the piezoelectric element is used as only an actuator and an additional accelerometer is added to the system for use as a sensor. In one embodiment, the system utilizes a linear control algorithm where system parameters are known, such as Lead-Lag, PID control, or opposite wave generation in order to actively control the actuation of the piezoelectric element. In some cases, the system utilizes a nonlinear control algorithm, using a microprocessor and power source, for adaptive control. On one embodiment, system structural health is monitored for significant resonant shifts over time due to impending structural failure.

In some cases, vibration and shock amplitude spikes to the structure are reduced as a result of the embedded piezoelectric conversion of mechanical energy to electrical energy and subsequent electrical resonant loading. The result is reduced shock and vibration amplification imposed on sensitive components such as oscillators and clocks. This reduction can lead to improved phase noise of a radio frequency system when subjected to vibrations outside of specified oscillator specifications, for example.

In some cases, the vibration sensitive components are oscillators, clocks, or other components that benefit from improved phase noise. In other cases, other vibration sensitive components such as lenses, mirrors, or other optics benefit from vibration damping. In many cases, other structural failures due to fatigue can be avoided by applying the system and method of the present disclosure.

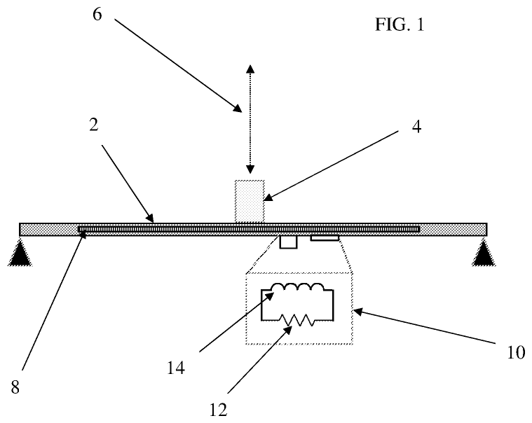

Referring to FIG. 1, one embodiment of the system of the present disclosure is shown. More specifically, a piezoelectric vibration absorption system is shown. There, a printed circuit board (PCB) 2 is shown with a vibration sensitive component 4 mounted on one face of the PCB. In use, the PCB experiences vibrations, shocks and the like in a general direction 6. In certain embodiments, a piezo patch transducer 8 is embedded in the circuit card and a tuned RL (resistor-inductor) circuit is surface mounted 10 to the circuit card assembly (CCA), where the tuned RL circuit comprises a resistor 12 and an inductor 14. In some cases, this system reduces shock and vibration amplification of a CCA, or other structure, at its natural frequency. The natural frequency is estimated using finite element analysis in conjunction with hand calculations. Using these estimations, the structure may be physically excited via a shaker table, or equivalent form of excitation, and the response measured in order to reconcile the differences between the finite analysis and the true nature of the structure.

It is understood that piezoelectric patches deflect when a voltage is applied to them and conversely a voltage is induced when an external force is applied to the piezoelectric patch. In one embodiment of the present disclosure, the feasibility of applying a piezoelectric patch to a circuit card assembly or electronic module and applying a shunting load circuit to the piezoelectric patch was explored. By optimally tuning the circuit to shunt the natural frequency of the structure, the resonant spike in response at the card was reduced. Reducing the resonant spike in the structure did not create a significant change in stiffness to the system except around the frequency in question.

It is understood that many applications of circuit card assemblies are subjected to high vibration environments, yet have vibration sensitive components such as oscillators and clocks mounted thereon. The addition of a vibration absorption solution on a circuit card assembly, or the like, can increase the longevity, accuracy, and physical integrity of the assembly and its components. FIG. 1 outlines one embodiment of the physical architecture of the present disclosure.

In one embodiment of the system of the present disclosure, a circuit card assembly was analyzed for its first natural frequency. A control circuit was then tuned appropriately in order to shunt the first natural frequency of the circuit card. The setup was tested under both sine sweep conditions as well as a random vibration profile. The shunting load circuit was applied to the setup and the center of the circuit card was monitored for its response, both shunted and un-shunted.

For this work, two piezoelectric patches were selected for vibration absorption applications. The two patches were different thicknesses and had different actuation forces that could be applied. The first had a lower operating voltage, larger electrical capacitance, less actuation force, and a slimmer construction compared to the second patch. The patches were bonded to a 0.040 inch thick FR-4 mock circuit board using an epoxy adhesive.

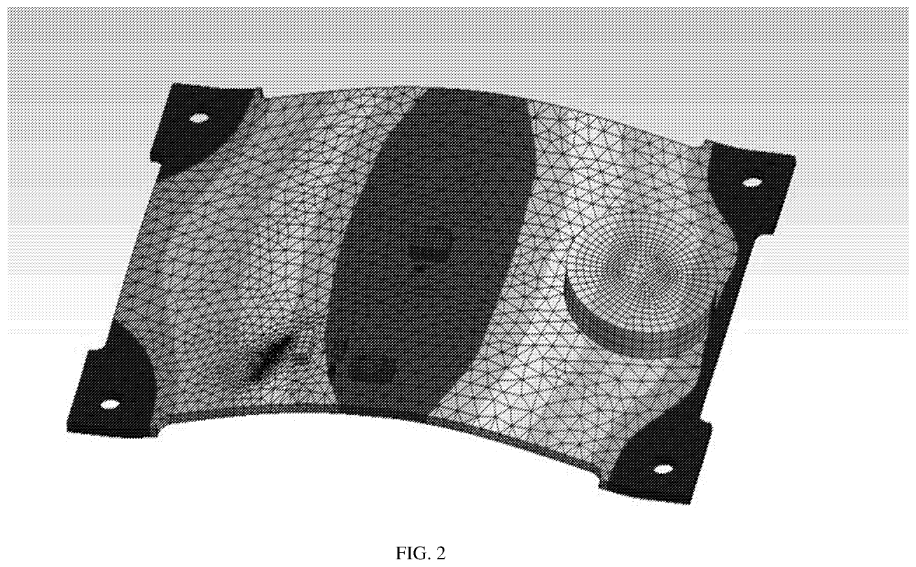

A modal analysis was conducted to estimate the first natural frequency of the circuit card setup. The accelerometer was modeled as a titanium slug bonded to the top of the circuit card. Both the circuit card and piezoelectric patch were modeled as FR-4, with perfect bonding to each other. The results shown in FIG. 2 are representative of a circuit board thickness of 0.060 inches thick. After running this thickness on a shaker, the conservative analysis of about 761 Hz yielded an experimental natural frequency of just over 800 Hz. In an attempt to capture multiple mode shapes effectively, the thickness of the card material was reduced to 0.040 inches thick, driving the natural frequency down to the 615 Hz to 650 Hz range. In one embodiment of this disclosure, the system can be applied to structures of nearly any form factor that are subject to deflections imposed by their environment. In certain embodiments, the system is effective for natural frequencies from 10's of Hertz to 100's of kilo-Hertz.

Still referring to FIG. 2, the first mode resonant frequency and mode shape of one embodiment of the present disclosure is shown. More specifically, FIG. 2 illustrates the mode shape that was to be attenuated during operation for one embodiment of the disclosure. The finite element model predicted a natural frequency of approximately 761 Hz for a structure that was 0.060″ inches thick. This mode shape (shape of deflection/excitation) under vibration is what was used to estimate the first mode natural frequency prior to tuning of the electrical system.

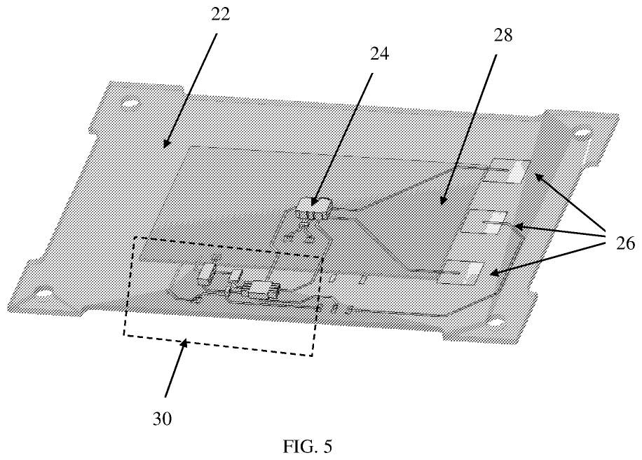

In another embodiment of the present disclosure, the circuit card architecture differed slightly from that in FIG. 1. There, a parallel shunting circuit was used (See, FIG. 5) as opposed to the series circuit defined in FIG. 1. Since resistance values were higher and more easily controlled by the governing equations, the parallel circuit was selected for further testing. The optimal inductor and resistor for each patch were found as follows:

$$\begin{matrix}Optimal Parallel Inductance and Resistance & \\ {L}_{OPTM}^{{RSP}_{PARALLEL}} = \frac{1}{{C}_{PZT}^{S} ( 1 - \frac{{K}_{ij}^{2}}{2} ) {ω}_{n}^{2}} \\ {R}_{OPTM}^{{RSP}_{PARALLEL}} = \frac{1}{\sqrt{2} {K}_{ij} {C}_{PZT}^{S} {ω}_{n}} & Equation 1\end{matrix}$$

where:
C_{PZT}^{S}≡Piezoelectric Patch Capacitance
Kᵢⱼ≡2 Dimensional Stiffness of Piezoelectric Patch
ωₙ≡natural frequency of system

Depending on the natural frequency and the capacitance of the of the piezoelectric element we can expect: R values to range from 100 ohms to 10000 kilo-ohms and L values to range from 10 mH to 100s of Henrys. See, e.g., the article by Viana and Steffen addressing Multimodal Vibration Damping through Piezoelectric Patches and Optimal Resonant Shunt Circuits in the J. of the Braz. Soc. of Mech. Sci. & Eng., July-September 2006, Vol. XXVIII, No. 3.

There are multiple component layouts and shunting schemes that can prove to be effective depending on the particular application. The test systems disclosed herein were performed with the circuit in parallel (due to lower inductance values). In some cases, (e.g., with higher inductance values) the resonant shunt circuit could be in series. There may be modest improvement in the effectiveness of vibration control depending on the shunt design used. Additionally, some systems will benefit from a focus on a single frequency mode and others will benefit from a multimodal approach.

In one example, a flat, random vibration profile was run on an Unholtz-Dickie T1000 shaker at an acceleration spectral density of 0.01 g²/Hz and sine sweeps were also conducted. The sine sweep data had similar results; however, it was less applicable to a real-world application since most real world environments are defined by spectra of random vibration frequencies, rather than a controlled sinusoidal sweep across the frequency range.

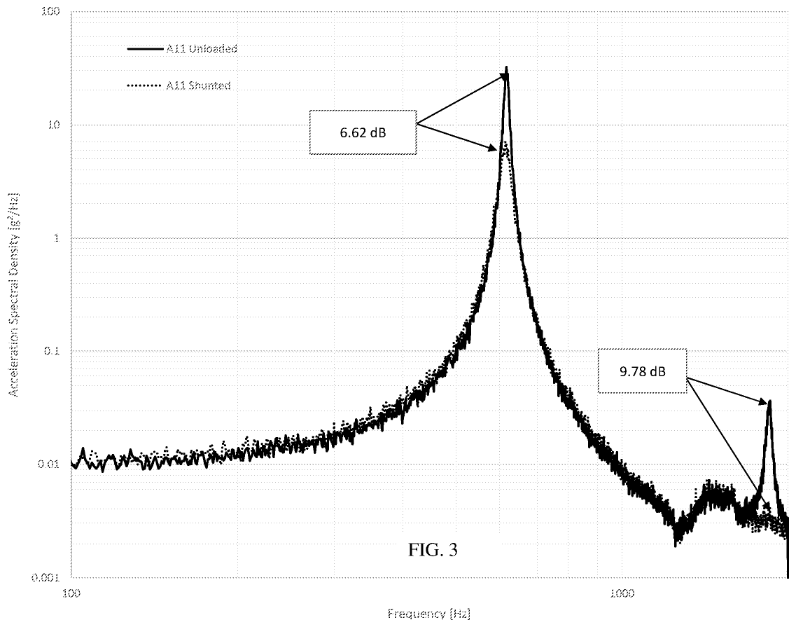

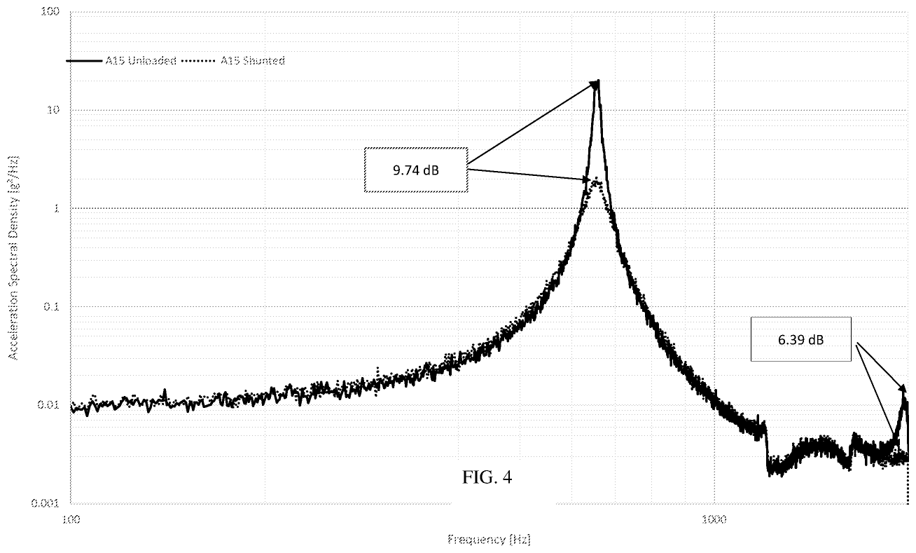

FIG. 3 and FIG. 4 show the effectiveness of the shunting circuit on the first harmonic mode of the circuit card shown in FIG. 5. During shunted testing, the piezoelectric patch was electrically loaded via the shunting circuit (e.g., the RL equivalent circuit). Referring to FIG. 3, a vibration frequency plot of a first embodiment of the present disclosure both shunted and un-shunted is shown. Referring to FIG. 4, a vibration frequency plot of a second embodiment of the present disclosure both shunted and un-shunted is shown. More specifically, the testing of a passive, resonant vibration absorber yielded results of a 6.62 dB attenuation in the first mode of the circuit card for the first absorber, and 9.74 dB of attenuation in the first mode of the circuit card for the second piezoelectric absorber. The second observable mode with this instrumentation led to a 9.78 dB attenuation of the first setup and a 6.39 dB attenuation in the second setup. It can also be noted that during the un-shunted testing, the piezoelectric was left in an “open-circuit” configuration. Open circuit piezoelectric elements tend to shunt vibrations inherently due to the inability to bleed off built up charge. It can be expected that this setup is actually more effective than captured in this initial testing.

The resulting total energy subjected to the response accelerometer in the first setup in the vertical axis was 25.19 Gᵣₘₛ, unloaded, and was reduced to 17.50 Gᵣₘₛ with the addition of the shunting circuit. The control location was subjected to 4.47 Gᵣₘₛ and the total energy reduction due to the addition of the absorber was 30.5%.

The resulting total energy subjected to the response accelerometer in the second setup in the vertical axis was 22.63 Gᵣₘₛ, unloaded, and was reduced to 13.25 Gᵣₘₛ with the addition of the shunting circuit. The control location was subjected to 4.48 Gᵣₘₛ and the total energy reduction due to the addition of the absorber was 41.9%.

Of the two patches tested, the second setup absorbed the most energy, and reduced the first vibration mode the most significantly. The second setup was also assessed for shock response absorption. When exposed to a 6 ms 14 g SRS (shock response spectrum) shock test, the second setup reduced the peak response from 424.0 g to 313.8 g. In certain embodiments of the system of the present disclosure, acceptable ranges are determined on a case by case basis as systems are designed. In one example, structural responses due to the application of this system have shown a reduction in vibration by an order of magnitude.

Referring to FIG. 5, one embodiment of the system of the present disclosure is shown. More specifically, a circuit card assembly (CCA) 22, or the like, comprises one or more oscillators 24 in need of a reduction of phase noise when operated in a vibrational environment. Here, several DC input pickup pads 26 are shown for powering the oscillator 24 and the RL equivalent circuit 30. In this embodiment, there is an embedded piezoelectric patch 28 for use for the reduction of phase noise of the oscillator (or other vibration sensitive device). In one embodiment of the present disclosure, the RL equivalent circuit, comprising an inductor and a resistor, allows tuning to any desired frequency, which will attenuate the corresponding vibration amplitudes experienced by the card and any devices/oscillators mounted thereon. In addition, improvements in the topology of the circuit make possible the simultaneous reduction of more than one vibration mode, if desired. Thus, the embedded piezoelectric patch 28 and the resonant shunt circuit 30 act much like a dynamic vibration absorber.

In certain embodiments of the system of the present disclosure, the natural frequency is chosen either by way of a finite element analysis model or by way of using real life shaker data. The actual shaker data is generally more accurate. After looking at the modal analysis results, the piezoelectric element is placed in a high strain location of the structure. In this work shown in the figures, the high strain location was at the center of the card because of symmetric bending. It is understood that each application will have a different optimized location. From there, the electrical system is optimized by selection of components that are effective in the natural frequency range as they relate to the inherent properties of the piezoelectric device (voltage out, capacitance, and the like).

In this work, the physical structures that were analyzed had low natural frequencies compared to natural frequencies that occur in electrical systems. (100s of Hz versus 1000s of Hz). Therefore in order to tune the shunt system effectively, extremely high inductance values were needed. In a tradition inductor, a higher inductance means a larger size. However, high inductance in an electrical circuit can be achieved with a synthetic inductor which allows for a much smaller package while still providing the same frequency response. Since this approach uses a Resistor-Inductor (RL) circuit, a synthetic RL circuit is created. The synthetic RL circuit is essentially a “high pass” filter that acts like a traditional RL circuit without the large coil for inductance. It is simply an operational amplifier (op-amp) with resistors and a capacitor that behaves similarly to a high inductance RL circuit without taking up much space for the frequencies needed in this application.

The electro mechanical portion of this disclosure has many applications, including but not limited to any flat geometry that is susceptible to vibration and shock. Some examples include circuit cards of nearly any form factor that are deployed on missiles, decoys, or exposed to pyro/gun/hypervelocity g-loading, or the like. Essentially, the disclosure is applicable to vibration stiffing on a circuit card for any sensitive components, not just oscillators. Alternative examples can include providing for the stability of structures used for optics. Certain embodiments of the system of the present disclosure provide improved phase noise performance to devices by using a piezoelectric module. In some cases, a circuit card of known size could contain an embedded piezoelectric patch which can accommodate interchangeable oscillators. In yet other embodiments, a piezoelectric element can be mounted to the surface of a structure rather than being embedded.

In another embodiment of the present disclosure, adaptive control can be used to reduce phase noise and/or provide vibration stiffing to a number of different types of devices in a variety of environments. A microcontroller can be used to address changing RL values to allow for adaptation to vibrations within any environment. In some cases, by using a microprocessor the system can be monitored in real time to provide for protection of the device against vibrational interference, fatigue, and/or damage and also to report on the health of the system's structure over time.

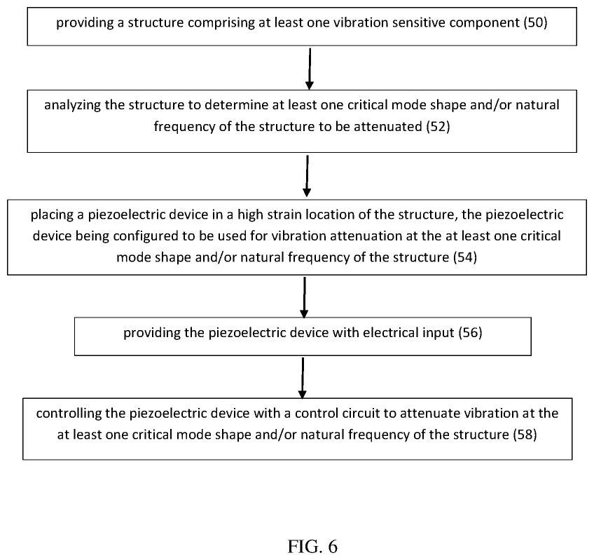

Referring to FIG. 6, one embodiment of a method according to the principles of the present disclosure is shown. More specifically, in one embodiment, a structure comprising at least one vibration sensitive component is provided 50, and that structure is analyzed to determine at least one critical mode shape and/or natural frequency of the structure to be attenuated 52. By placing a piezoelectric device in a high strain location of the structure, the piezoelectric device can be configured to be used for vibration attenuation at the at least one critical mode shape and/or natural frequency of the structure 54. Providing the piezoelectric device with electrical input 56, allows for controlling the piezoelectric device with a control circuit to attenuate vibration at the at least one critical mode shape and/or natural frequency of the structure 58.

The computer readable medium as described herein can be a data storage device, or unit such as a magnetic disk, magneto-optical disk, an optical disk, or a flash drive. Further, it will be appreciated that the term “memory” herein is intended to include various types of suitable data storage media, whether permanent or temporary, such as transitory electronic memories, non-transitory computer-readable medium and/or computer-writable medium.

It will be appreciated from the above that the invention may be implemented as computer software, which may be supplied on a storage medium or via a transmission medium such as a local-area network or a wide-area network, such as the Internet. It is to be further understood that, because some of the constituent system components and method steps depicted in the accompanying Figures can be implemented in software, the actual connections between the systems components (or the process steps) may differ depending upon the manner in which the present invention is programmed. Given the teachings of the present invention provided herein, one of ordinary skill in the related art will be able to contemplate these and similar implementations or configurations of the present invention.

It is to be understood that the present invention can be implemented in various forms of hardware, software, firmware, special purpose processes, or a combination thereof. In one embodiment, the present invention can be implemented in software as an application program tangible embodied on a computer readable program storage device. The application program can be uploaded to, and executed by, a machine comprising any suitable architecture.

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

What is claimed:

1. A method of reducing the motion of a vibration sensitive component, comprising:
providing a structure comprising at least one vibration sensitive component;
analyzing the structure to determine at least one critical mode shape and/or natural frequency of the structure to be attenuated;
placing a piezoelectric device in a high strain location of the structure, the piezoelectric device being configured to be used for vibration attenuation at the at least one critical mode shape and/or natural frequency of the structure;
providing the piezoelectric device with electrical input; and
controlling the piezoelectric device with a control circuit to attenuate vibration at the at least one critical mode shape and/or natural frequency of the structure.

2. The method of reducing the motion of a vibration sensitive component according to claim 1, wherein the piezoelectric device is embedded in the structure.

3. The method of reducing the motion of a vibration sensitive component according to claim 1, wherein the vibration sensitive component is an oscillator and/or a clock.

4. The method of reducing the motion of a vibration sensitive component according to claim 3, wherein phase noise is reduced.

5. The method of reducing the motion of a vibration sensitive component according to claim 1, wherein the vibration sensitive component is an optical device.

6. The method of reducing the motion of a vibration sensitive component according to claim 1, wherein the structure is a circuit card assembly.

7. The method of reducing the motion of a vibration sensitive component according to claim 1, wherein the control circuit includes but is not limited to a resonant shunt circuit of an inductor and resistor tuned to at least one critical frequency or an active control mechanism including an electrical design that provides a negative waveform of that of the environment.

8. The method of reducing the motion of a vibration sensitive component according to claim 1, further comprising tuning an electrical shunt circuit and electrically connecting it to the piezoelectric device, thereby shunting structural excitations that occur in the structure and/or the connected vibration sensitive components.

9. The method of reducing the motion of a vibration sensitive component according to claim 7, further comprising providing adaptive control of the control circuit.

10. The method of reducing the motion of a vibration sensitive component according to claim 7, further comprising feedback control to accurize the active control of the control circuit.

11. The method of reducing the motion of a vibration sensitive component according to claim 9, further comprising a microcontroller to address changing resistor and inductor values to allow for adaptation to vibrations within the environment.

12. The method of reducing the motion of a vibration sensitive component according to claim 1, further comprising designing the structure around one or more vibration sensitive components.

13. A system for reducing the motion of a vibration sensitive component, comprising:
a structure comprising at least one vibration sensitive component, the structure having at least one critical mode shape and/or natural frequency;
a piezoelectric device located in a high strain location of the structure, the piezoelectric device being configured to be used for vibration attenuation of the at least one critical mode shape and/or natural frequency of the structure; and
a control circuit in electrical connection with the piezoelectric device for controlling vibration attenuation at the at least one critical mode shape and/or natural frequency of the structure.

14. The system for reducing the motion of a vibration sensitive component according to claim 14, wherein the control circuit includes but is not limited to a resonant shunt circuit of an inductor and resistor tuned to at least one critical frequency, or an active control mechanism including an electrical design that provides a negative waveform of that of the environment.

15. The system for reducing the motion of a vibration sensitive component according to claim 13, further comprising tuning an electrical shunt circuit electrically connected to the piezoelectric device, thereby shunting structural excitations that occur in the structure and/or the connected vibration sensitive components.

16. The system for reducing the motion of a vibration sensitive component according to claim 13, further comprising a synthetic inductor.

17. The system for reducing the motion of a vibration sensitive component according to claim 14, further comprising adaptive control of the control circuit.

18. The system for reducing the motion of a vibration sensitive component according to claim 13, wherein the structure is a circuit card assembly and the piezoelectric device is embedded in the structure.

19. The system for reducing the motion of a vibration sensitive component according to claim 14, further comprising one or more of a processor, a proportional-integral-derivative (PID) controller, an adaptive controller for the control circuit, an a lead lag compensator.
